(19) United States
(12) Patent Application Publication
(10) Pub. No.: US 2026/0150651 A1
(43) Pub. Date: May 28, 2026

(54) Wiring Substrate, Method for Manufacturing Structural Component, and Display Apparatus

(71) Applicants: BOE MLED TECHNOLOGY CO., LTD., Beijing (CN); BOE TECHNOLOGY GROUP CO., LTD., Chaoyang District, Beijing (CN)

(72) Inventors: Xiaofei Xu, Beijing (CN); Qibing Gu, Beijing (CN); Lili Jia, Beijing (CN); Zhongbao Wu, Beijing (CN); Jingran Niu, Beijing (CN); Enmin Niu, Beijing (CN); Shouwei Wang, Beijing (CN); Xin Wang, Beijing (CN)

(21) Appl. No.: 19/122,777

(22) PCT Filed: Jul. 26, 2024
(86) PCT No.: PCT/CN2024/107789

§ 371 Date: Apr. 21, 2025

(30) Foreign Application Priority Data
Aug. 8, 2023 (CN) 202310997100.5

(51) Int. Cl. H10W 20/43; H10W 20/00

(52) U.S. Cl. CPC H10W 20/43; H10W 20/067

(57) ABSTRACT

A wiring substrate includes a substrate. The substrate includes a first region including two first trunk regions and a first connection region, and a second region including two second trunk regions and a second connection region. The first trunk regions extend in a first direction and are spaced apart by a first interval in a second direction. Ends of the first connection region are respectively connected to ends of the first trunk regions located on a same side. The second trunk regions extend in the first direction and are spaced apart by a second interval in the second direction. Ends of the second connection region are respectively connected to ends of the second trunk regions located on a same side. A first trunk region is located in a second opening of the second region, and a second trunk region is located in a first opening of the first region.

### CROSS-REFERENCE TO RELATED APPLICATIONS

This application is the United States national phase of International Patent Application No. PCT/CN2024/107789 filed Jul. 26, 2024, and claims priority to Chinese Patent Application No. 202310997100.5 filed Aug. 8, 2023, the disclosures of which are hereby incorporated by reference in their entireties.

### BACKGROUND OF THE INVENTION

### Field of the Invention

The present disclosure relates to the field of display technologies, and in particular, to a wiring substrate, a method for manufacturing a structural component, and a display apparatus.

### Description of Related Art

With the development of light-emitting diode technologies, backlight sources using mini light-emitting diodes (Mini-LEDs) and micro light-emitting diodes (Micro-LEDs) have been widely used. A size of the Mini-LED is approximately in a range of 100 μm to 300 μm, and a size of the Micro-LED is approximately less than 100 μm. Due to the advantages such as small size, high brightness and high contrast, Mini-LEDs and Micro-LEDs, when applied to a backlight module, can make fine adjustments to the backlight, so as to realize high dynamic range (HDR) display, thereby winning more and more attention.

### SUMMARY OF THE INVENTION

In an aspect, a wiring substrate is provided. The wiring substrate includes a substrate. The substrate includes at least one first region and at least one second region. A first region includes two first trunk regions and a first connection region; the two first trunk regions extend in a first direction and are spaced apart by a first interval in a second direction; ends of the first connection region are respectively connected to ends of the two first trunk regions located on a same side; and the first region has a first opening. The second region includes two second trunk regions and a second connection region; the two second trunk regions extend in the first direction and are spaced apart by a second interval in the second direction; ends of the second connection region are respectively connected to ends of the two second trunk regions located on a same side; and the second region has a second opening. An orientation of the second opening is opposite to an orientation of the first opening. The first direction and the second direction intersect. A first trunk region of the first region is located in the second opening, and a second trunk region of the second region is located in the first opening.

In some embodiments, a dimension of the first trunk region in the first direction is equal to a dimension of the second trunk region in the first direction; and/or a dimension of the first trunk region in the second direction is equal to a dimension of the second trunk region in the second direction.

In some embodiments, the first interval is equal to the second interval.

In some embodiments, the first interval is greater than a dimension of the second trunk region in the second direction, and is less than or equal to 1.5 times the dimension of the second trunk region in the second direction. The second interval is greater than a dimension of the first trunk region in the second direction, and is less than or equal to 1.5 times the dimension of the first trunk region in the second direction.

In some embodiments, a plurality of through holes are provided between a first region and a second region that are adjacent; a connection structure is provided between two adjacent through holes; and the connection structure is used to connect and fix the first region and the second region that are adjacent.

In some embodiments, the first interval is greater than 2 times a dimension of the second trunk region in the second direction, and is less than or equal to 2.5 times the dimension of the second trunk region in the second direction. The second interval is greater than 2 times a dimension of the first trunk region in the second direction, and is less than or equal to 2.5 times the dimension of the first trunk region in the second direction.

In some embodiments, the at least one first region includes a plurality of first regions sequentially arranged in the second direction, and the at least one second region includes a plurality of second regions sequentially arranged in the second direction. Two first trunk regions, which respectively belong to two adjacent first regions and have therebetween a smallest distance in the second direction, are located in a second opening of a same second region. Two second trunk regions, which respectively belong to two adjacent second regions and have therebetween a smallest distance in the second direction, are located in a first opening of a same first region.

In some embodiments, the substrate further includes a third region, and the third region extends in the first direction and is located between a first trunk region and a second trunk region that are outermost in the second direction.

In some embodiments, a plurality of through holes are provided between a first region and a second region that are adjacent, a plurality of through holes are provided between a first region and a third region that are adjacent, a plurality of through holes are provided between adjacent first regions, a plurality of through holes are provided between adjacent second regions, and a plurality of through holes are provided between a second region and a third region that are adjacent; a connection structure is provided between two adjacent through holes; the connection structure is used to connect and fix the first region and the second region that are adjacent, the first region and the third region that are adjacent, the adjacent first regions, the adjacent second regions, or the second region and the third region that are adjacent.

In some embodiments, each first trunk region of the first region is provided with a plurality of electronic elements arranged at intervals in the first direction, and each second trunk region of the second region is provided with a plurality of electronic elements arranged at intervals in the first direction; a distance between two adjacent electronic elements in the first direction is D1, a dimension of the first trunk region in the second direction and a dimension of the second trunk region in the second direction are both D2; a width of the connection structure in a direction perpendicular to a boundary, connected to the connection structure, of a first region or a second region is M; and D1, D2 and M satisfy D2=(D1−3M)/3.

In some embodiments, the width M of the connection structure in the direction perpendicular to the boundary, connected to the connection structure, of the first region or the second region is in a range of 1 mm to 2 mm.

In some embodiments, each of the first connection region of the first region and the second connection region of the second region is provided with a first connector; and an orthographic projection of a first connector corresponding to the first connection region on the substrate only partially overlaps with the first connection region, and an orthographic projection of a first connector corresponding to the second connection region on the substrate only partially overlaps with the second connection region.

In some embodiments, each of each first trunk region of the first region and each second trunk region of the second region is provided with a plurality of driving elements; and a driving element is configured to control at least one electronic element in a same region.

In another aspect, a method for manufacturing a structural component is provided. The method includes: dividing a substrate into first regions, second regions and fourth regions; removing portions of the fourth region, so that a plurality of through holes are formed in the fourth region and arranged at intervals, and a connection structure is formed between two adjacent through holes; arranging wiring on the first regions and the second regions; arranging electronic elements on each first trunk region of the first region and each second trunk region of the second region; mounting first connectors on the first connection regions and the second connection regions; and cutting connection structures, so that each of any first region and any second region that are independent of each other constitute a structural component. A first region includes two first trunk regions and a first connection region; the two first trunk regions extend in a first direction and are spaced apart by a first interval in a second direction; ends of the first connection region are respectively connected to ends of the two first trunk regions located on a same side; a second region includes two second trunk regions and a second connection region; the two second trunk regions extend in the first direction and are spaced apart by a second interval in the second direction; ends of the second connection region are respectively connected to ends of the two second trunk regions located on a same side; the second region has a second opening; an orientation of the second opening is opposite to an orientation of the first opening; a fourth region is located between a first region and a second region that are adjacent, a fourth region is located between adjacent first regions, and a fourth region is located between adjacent second regions; and the first direction and the second direction intersect.

In some embodiments, after each of any first region and any second region that are independent of each other constitute a structural component, the method further includes: providing a adapter circuit board; and mounting a plurality of structural components on the adapter circuit board, a first connector of each structural component being connected to a second connector. The adapter circuit board extends in the second direction, and a plurality of second connectors are provided on the adapter circuit board.

In some embodiments, two structural components adjacent to each other in the first direction are arranged on two sides of the adapter circuit board in an axisymmetric manner.

In yet another aspect, a display apparatus is provided. The display apparatus includes a display panel and structural components formed by the method for manufacturing a structural component as described in any of the above embodiments.

### BRIEF DESCRIPTION OF THE DRAWINGS

In order to describe technical solutions in some embodiments of the present disclosure more clearly, the accompanying drawings to be used in some embodiments of the present disclosure will be introduced briefly. However, the accompanying drawings to be described below are merely some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a structural diagram of a display apparatus, in accordance with some embodiments;

FIG. 2 is a structural diagram of a display panel, in accordance with some embodiments;

FIG. 3A is a structural diagram of a wiring substrate, in accordance with some embodiments;

FIG. 3B is a structural diagram of another wiring substrate, in accordance with some embodiments;

FIG. 4 is a partial enlarged view of the A region in FIG. 3A;

FIG. 5 is a structural diagram of yet another wiring substrate, in accordance with some embodiments;

FIGS. 6A to 6D are flow diagrams showing manufacturing processes of a structural component, in accordance with some embodiments;

FIG. 7 is a structural diagram of a light-emitting substrate, in accordance with some embodiments;

FIG. 8 is a partial enlarged view of the B region in FIG. 7;

FIG. 9A is a partial enlarged view of the C region in FIG. 8; and

FIG. 9B is another partial enlarged view of the C region in FIG. 8.

### DESCRIPTION OF THE INVENTION

The technical solutions in some embodiments of the present disclosure will be described clearly and completely with reference to the accompanying drawings. However, the described embodiments are merely some but not all embodiments of the present disclosure. All other embodiments obtained by a person of ordinary skill in the art based on embodiments of the present disclosure shall be included in the protection scope of the present disclosure.

Unless the context requires otherwise, throughout the specification and the claims, the term “comprise” and other forms thereof such as the third-person singular form “comprises” and the present participle form “comprising” are construed as an open and inclusive meaning, i.e., “including, but not limited to”. In the description of the specification, the terms such as “one embodiment,” “some embodiments,” “exemplary embodiments,” “example,” “specific example,” or “some examples” are intended to indicate that specific features, structures, materials, or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described may be included in any one or more embodiments or examples in any suitable manner.

The terms “first” and “second” are used for descriptive purposes only, and are not to be construed as indicating or implying a relative importance or implicitly indicating the number of indicated technical features. Thus, features defined with “first” or “second” may explicitly or implicitly include one or more of the features. In the description of the embodiments of the present disclosure, the term “multiple”, “a plurality of” or “the plurality of” means two or more unless otherwise specified.

In the description of some embodiments, the expressions “connected” and derivatives thereof may be used. For example, the term “connected” may be used in the description of some embodiments to indicate that two or more components are in direct physical or electrical contact with each other. The embodiments disclosed herein are not necessarily limited to the content herein.

The phrase “A and/or B” includes the following three combinations: only A, only B, and a combination of A and B.

The phrase “configured to” used herein has an open and inclusive meaning, which does not exclude devices that are applicable to or configured to perform additional tasks or steps.

In addition, the phrase “based on” used is meant to be open and inclusive, since a process, step, calculation or other action that is “based on” one or more of the stated conditions or values may, in practice, be based on additional conditions or value exceeding those stated.

The term such as “about,” “substantially,” or “approximately” as used herein includes a stated value and an average value within an acceptable range of deviation of a particular value determined by a person of ordinary skill in the art, considering measurement in question and errors associated with measurement of a particular quantity (i.e., limitations of a measurement system).

The term such as “parallel,” “perpendicular,” or “equal” as used herein includes a stated condition and a condition similar to the stated condition. A range of the similar condition is within an acceptable deviation range, and the acceptable deviation range is determined by a person of ordinary skill in the art, considering measurement in question and errors associated with measurement of a particular quantity (i.e., the limitations of a measurement system). For example, the term “parallel” includes absolute parallelism and approximate parallelism, and an acceptable range of deviation of the approximate parallelism may be, for example, a deviation within 5°; the term “perpendicular” includes absolute perpendicularity and approximate perpendicularity, and an acceptable range of deviation of the approximate perpendicularity may also be, for example, a deviation within 5°; and the term “equal” includes absolute equality and approximate equality, and an acceptable range of deviation of the approximate equality may be that, for example, a difference between the two that are equal is less than or equal to 5% of either of the two.

It will be understood that, when a layer or element is referred to as being on another layer or substrate, it may be that the layer or element is directly on the another layer or substrate, or it may be that intermediate layer(s) exist between the layer or element and the another layer or substrate.

Some embodiments of the present disclosure provide a display apparatus. The display apparatus may be any apparatus that displays an image whether in motion (e.g., a video) or stationary (e.g., a still image), and whether textual or graphical.

For example, the display apparatus may be a mobile phone, a wireless apparatus, a personal digital assistant (PDA), a wearable device, an augmented reality (AR) device, a virtual reality (VR) device, a hand-held or portable computer, a GPS receiver/navigator, a camera, an MP4 video player, a video camera, a game console, a watch, a clock, a calculator, a television monitor, a flat panel display, a computer monitor, an automobile display (e.g., an odometer display), a cockpit controller and/or display, a display of camera views (e.g., a display of a rear-view camera in a vehicle), an electronic photo, an electronic billboard or sign, a projector, or a packaging and aesthetic structure (e.g., a display for displaying an image of a piece of jewelry), etc.

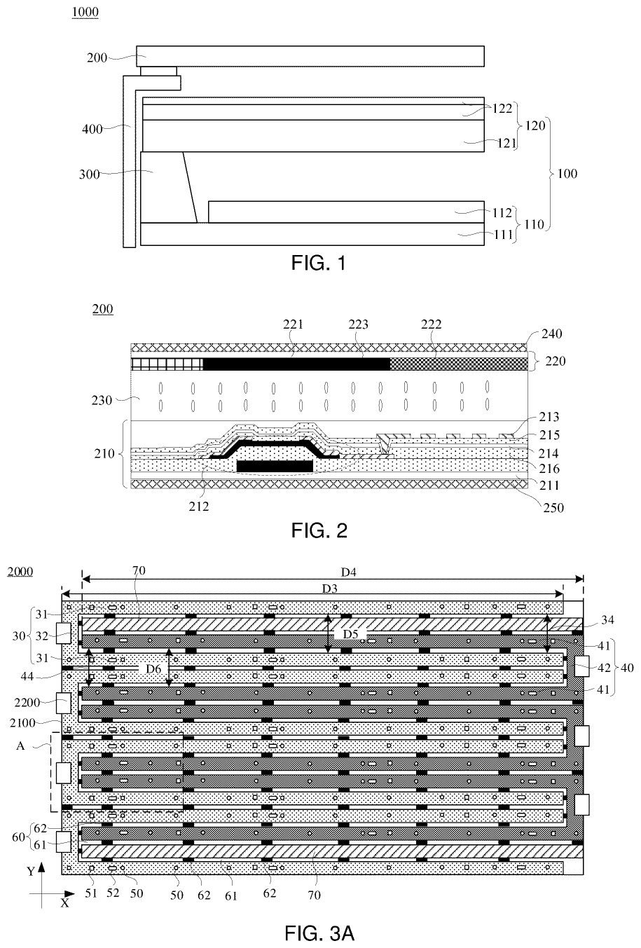

In some embodiments, the display apparatus may be a liquid crystal display (LCD) apparatus. Referring to FIG. 1, in a case where the display apparatus 1000 is the liquid crystal display apparatus, the display apparatus 1000 may include a backlight module 100 and a display panel 200. Of course, the embodiments of the present disclosure are not limited thereto, and the display apparatus 1000 may also include other structures or devices. For example, as shown in FIG. 1, the display apparatus 1000 may further include a middle frame 300, an outer frame 400, and a glass cover plate (not shown in FIG. 1) disposed on a display side of the display panel 200, etc., which will not be provided in detail here, as long as the same technical concept as the present disclosure is applied.

The display panel 200 includes a display side and a non-display side. The display side refers to a side of the display panel 200 for displaying images (an upper side of the display panel 200 in FIG. 1), and the non-display side refers to another side opposite to the display side. The backlight module 100 is disposed on the non-display side of the display panel 200 (a lower side of the display panel 200 in FIG. 1), and the backlight module 100 is used for providing a backlight source for the display panel 200.

Referring to FIG. 2, in the case where the display apparatus 1000 is the liquid crystal display apparatus, the display panel 200 may be a liquid crystal display panel. In this case, the display panel 200 may include an array substrate 210, an opposite substrate 220, and a liquid crystal layer 230 disposed between the array substrate 210 and the opposite substrate 220.

The array substrate 210 is provided with thin film transistors (TFTs) 212 and pixel electrodes 213 that are located on a first substrate 211. The thin film transistor 212 includes an active layer, a source, a drain, a gate and a gate insulating layer, the source and the drain are in contact with the active layer, and the pixel electrode 213 is electrically connected to the drain of the thin film transistor 212.

In some embodiments, as shown in FIG. 2, the array substrate 210 further includes common electrode(s) 214 disposed on the first substrate 211. The pixel electrode 213 and the common electrode 214 may be arranged in different layers. In this case, as shown in FIG. 2, a first insulating layer 215 is provided between the pixel electrode 213 and the common electrode 214. In a case where the common electrode 214 is disposed between the thin film transistor 212 and the pixel electrode 213, as shown in FIG. 2, a second insulating layer 216 is also provided between the common electrode 214 and the thin film transistor 212.

The pixel electrode 213 and the common electrode 214 may be arranged in the same layer (not shown in the figure). In this case, the pixel electrode 213 and the common electrode 214 are each of a comb structure including a plurality of strip-shaped sub-electrodes. In some other embodiments, the common electrode 214 may be disposed in the opposite substrate 220.

As shown in FIG. 2, the opposite substrate 220 may include a color filter layer 222 disposed on a second substrate 221. In this case, the opposite substrate 220 may also be referred to as a color filter (CF) substrate. In a case where the backlight module 100 is used for emitting white light, the color filter layer 222 includes at least red photoresist units, green photoresist units and blue photoresist units, and the red photoresist units, the green photoresist units and the blue photoresist units are directly opposite to sub-pixels in the display panel 200 one by one. The opposite substrate 220 further includes a black matrix pattern 223 disposed on the second substrate 221, and the black matrix pattern 223 is used for separating the red photoresist units, the green photoresist units and the blue photoresist units.

As shown in FIG. 2, the display panel 200 may further include a first polarizer 240 disposed on a side of the opposite substrate 220 away from the liquid crystal layer 230, and a second polarizer 250 disposed on a side of the array substrate 210 away from the liquid crystal layer 230. In addition, the display panel 200 may further include other film layers or structures, which are not listed one by one in the embodiments of the present disclosure.

As shown in FIG. 1, the backlight module 100 may include a light-emitting substrate 110 and an optical film 120 disposed on a side of the light-emitting substrate 110 close to the display panel 200. The light-emitting substrate 110 may emit white light; alternatively, the light-emitting substrate 110 may emit light of another color, and the light of another color is directed to the display panel 200 after color conversion by the optical film 120. The optical film 120 may include a diffuser plate and/or an optical brightness enhancement film, which is not specifically limited in the embodiments of the present disclosure. The diffusion plate has a scattering and diffusion effect, and is capable of further mixing the white light uniformly. The optical brightness enhancement film is capable of improving the light extraction efficiency of the backlight module 100. In addition, the backlight module 100 may further include other film layers or structures, which are not listed one by one in the embodiments of the present disclosure.

As shown in FIG. 1, the light-emitting substrate 110 includes a backplane 111 and a light source 112 disposed on the backplane 111. The light source 112 consists of a plurality of light-emitting elements (e.g., Mini-LED chips or Micro-LED chips) arranged in an array. The light-emitting substrate 110 and the optical film 120 have a light mixing interval therebetween. The light-emitting elements may be equivalent to point light sources. Light emitted by adjacent light-emitting elements is initially mixed within the light mixing interval H and then directed to the optical film 120, and is then directed to the display panel 200 after being further uniformized by the optical film 120. It will be understood that light finally incident on the display panel can be equivalent to light emitted by a surface light source.

In some embodiments, in some display products with a large light mixing interval H (for example, greater than 20 mm), an interval between adjacent light-emitting elements in the light-emitting substrate 110 is large.

In the related art, multiple light-emitting elements arranged in a row direction are disposed on a strip-shaped circuit board, and a first connector header is fixed to an end of each strip-shaped circuit board. When a plurality of strip-shaped circuit boards are arranged to assemble to a light-emitting substrate, an adapter circuit board is also required. Second connector headers are fixed on the adapter circuit board. The first connector header of each strip-shaped circuit board is connected to a single second connector header on the adapter circuit board. The adapter circuit board can be connected to an external circuit (e.g., a driver circuit board) through a flexible printed circuit (FPC). This solution requires that all strip-shaped circuit boards are assembled and fixed to the adapter circuit board one by one, which makes assembly difficult and consumes a large number of connectors, which is not conducive to reducing the manufacturing cost of the light-emitting substrate.

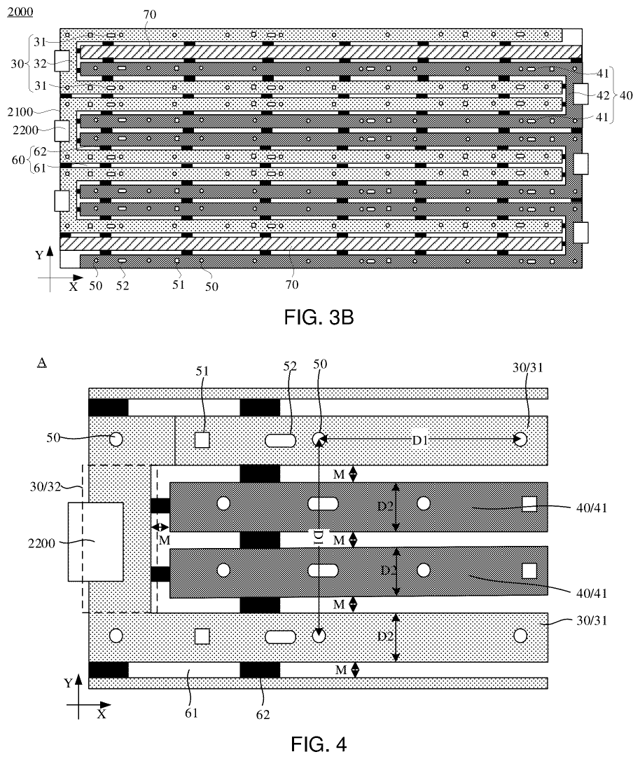

In order to solve the above technical problems, the embodiments of the present disclosure provide a wiring substrate 2000, which can be used to manufacturing a structural component. The structural component is, for example, a light-emitting structural component. Referring to FIGS. 3A and 4, the wiring substrate 2000 includes a substrate 2100, and the substrate 2100 includes first region(s) 30 and second region(s) 40. In FIG. 3A, in order to clearly show boundaries and positions of the first region 30 and the second region 40, different types of filling patterns are used for the two regions. The substrate 2100 may be made of any one of glass, quartz, sapphire, ceramic, and the like; alternatively, the substrate 2100 is made of a semiconductor material, such as any one of: a single-crystal semiconductor substrate or polycrystal semiconductor substrate with a base material such as silicon or silicon carbide, a compound semiconductor such as silicon germanium, a silicon-on-insulator (SOI), and the like; alternatively, the substrate 2100 is made of an organic resin material such as epoxy resin, triazine, silicon resin, or polyimide. The substrate 2100 may also be a FR4-type printed circuit board (PCB), or a flexible PCB that is prone to deformation. Alternatively, the substrate 2100 may be made of any one of: a ceramic material such as silicon nitride, AlN or Al₂O₃, a metal or metal compound, and a metal core PCB (MCPCB) or metal copper clad laminate (MCCL).

The first region 30 includes two first trunk regions 31 and a first connection region 32. The two first trunk regions 31 extend in a first direction X and are spaced apart by a first interval D5 in a second direction Y. That is, the first interval D5 refers to a distance between the two first trunk regions 31 in the second direction Y. Ends of the first connection region 32 are respectively connected to ends of the two first trunk regions 31 located on the same side (e.g., left ends in FIG. 3A). The first region 30 has a first opening 34. The first opening 34 refers to a region between the two first trunk regions 31. The first opening 34 is oriented in a direction away from the first connection region 32, that is, in a direction from left to right in FIG. 3A. The first region 30 is of a U-shaped structure. The first direction X and the second direction Y intersect. For example, the first direction X is perpendicular to the second direction Y.

The second region 40 includes two second trunk regions 41 and a second connection region 42. The two second trunk regions 41 extend in the first direction X and are spaced apart by a second interval D6 in the second direction Y. That is, the second interval D6 refers to a distance between the two second trunk regions 41 in the second direction Y. Ends of the second connection region 42 are respectively connected to ends of the two second trunk regions 41 located on the same side (e.g., right ends in FIG. 3A). That is, the second region 40 is of a U-shaped structure.

The second region 40 has a second opening 44. The second opening 44 refers to a region located between the two second trunk regions 41. An orientation of the second opening 44 (a direction from right to left along the first direction X in FIG. 3A) is opposite to the orientation of the first opening 34 (the direction from left to right along the first direction X in FIG. 3A); therefore, the first trunk region 31 can extend into the second opening 44, and the second trunk region 41 can extend into the first opening 34. For example, one first trunk region 31 of the first region 30 is located in the second opening 44, and one second trunk region 41 of the second region 40 is located in the first opening 34, which is conducive to increasing the space utilization of the substrate 2100. Each of any first region 30 and any second region 40 is used to form an independent structural component (e.g., a light-emitting structural component that can be used as a light source), and a single wiring substrate 2000 may be used to manufacture a plurality of structural components. Moreover, the first region 30 and each second region 40 are of a U-shaped structure. In a case where light-emitting substrates have the same size and the same arrangement density, compared with a linear light-emitting structural component, the U-shaped light-emitting structural component may reduce the usage amount of light-emitting structural components and the usage amount of connectors, which is conducive to reducing the manufacturing cost of the light-emitting substrate composed of multiple light-emitting structural components and reducing the manufacturing cost of the display apparatus 1000.

Moreover, compared with setting the first region 30 and the second region 40 in a comb shape, setting the first region 30 and the second region 40 in a U shape has better universality and can be applied to backlight products of various sizes. When setting a light-emitting substrate, a quantity and arrangement density of the U-shaped light-emitting structural components are flexibly set according to the size of the light-emitting substrate.

In some embodiments, referring to FIG. 3A, a dimension D3 of the first trunk region 31 in the first direction X is equal to a dimension D4 of the second trunk region 41 in the first direction X. And/or, referring to FIG. 4, a dimension of the first trunk region 31 in the second direction Y is equal to a dimension of the second trunk region 41 in the second direction Y, and the dimensions of the first trunk region 31 and the second trunk region 41 in the second direction Y are both D2. In this way, the first trunk region 31 and the second trunk region 41 having the same size and the same shape may be formed. The first trunk region 31 and the second trunk region 41 are used for an arrangement of electronic elements 50. The electronic elements 50 may be, for example, light-emitting elements, sensors, or other elements arranged in an array. The first trunk region 31 and the second trunk region 41 have the same size and the same shape, which is conducive to improving the uniformity of the arrangement of the electronic elements 50 on the first trunk region 31 and the second trunk region 41.

It will be understood that, in the case where the electronic elements 50 are light-emitting elements, a structural component consisting of the first region 30 (or the second region 40) and electronic elements 50 on the first region 30 (or the second region 40) is a light-emitting component. From the perspective of the type of the light-emitting element, the light-emitting element may be an LED with quantum well junction, an LED with columnar structure, an LED with double heterojunction, etc. The light-emitting element may also include an encapsulation structure on a light-emitting side of an LED. The encapsulation structure may be made of a transparent material, and its surface may be a curved surface or a hemispherical surface. From the perspective of the size of the light-emitting element, the light-emitting element may be a structure with a size miniaturized to the order of hundreds of microns. For example, a light-emitting area of an LED may be less than 1 mm², or the light-emitting area of the LED may be less than 10000 μm², or the light-emitting area of the LED may be less than 3000 μm², or the light-emitting area of the LED may be less than 700 μm². Of course, the embodiments of the present disclosure are not limited thereto, and the light-emitting elements may also adopt light-emitting elements of other structures, as long as the same technical ideas as those of the present disclosure are applied.

In some embodiments, as shown in FIG. 3A, the first interval D5 is equal to the second interval D6. In this way, the first region 30 and the second region 40 having the same size and the same shape may be formed, so that the first region 30 and the second region 40 may form structural components of the same shape, improving consistency and universality of the structural component.

For example, a dimension of the first connection region 32 of the first region 30 in the first direction X is equal to a dimension of the second connection region 42 of the second region 40 in the first direction X. Since the first interval D5 is equal to the second interval D6, it can be seen that a dimension of the first connection region 32 of the first region 30 in the second direction Y is equal to a dimension of the second connection region 42 of the second region 40 in the second direction Y. In this way, the first trunk region 31 of the first region 30 may be completely located within the second interval D6 of the second region 40, and the second trunk region 41 of the second region 40 may be completely located within the first interval D5 of the first region 30, which is conducive to further improving the space utilization of the wiring substrate 2000 and reducing the manufacturing cost of the wiring substrate 2000.

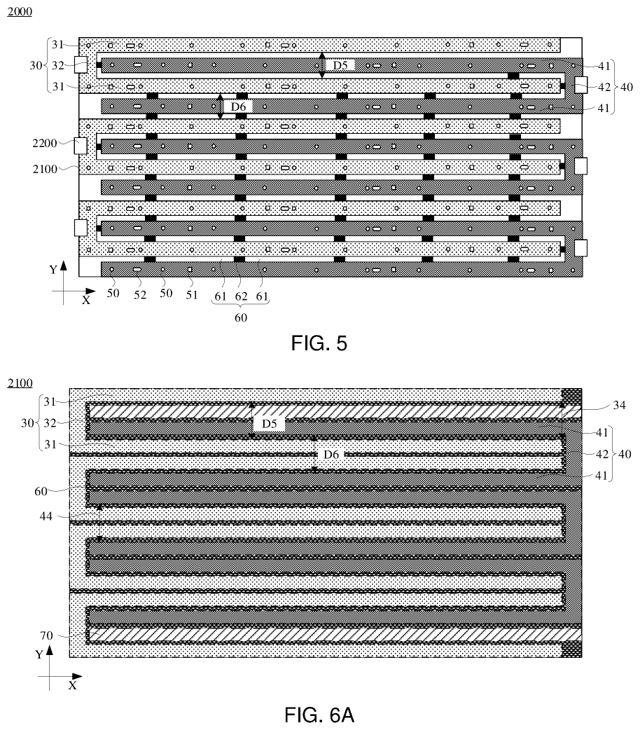

In some embodiments, referring to FIG. 5, the first interval D5 is greater than the dimension D2 of the second trunk region 41 in the second direction Y and is less than or equal to 1.5 times the dimension D2 of the second trunk region 41 in the second direction Y, that is, D2<D5≤1.5D2. In this case, one second trunk region 41 of the second region 40 is located in the first interval D5 of one first region 30, and another second trunk region 41 is located between two adjacent first regions 30. That is, each first interval D5 is provided therein with only one second trunk region 41.

The second interval D6 is greater than the dimension D2 of the first trunk region 31 in the second direction Y and is less than or equal to 1.5 times the dimension D2 of the first trunk region 31 in the second direction, that is, D2<D6≤1.5D2. In this case, one first trunk region 31 of the first region 30 is located within the second opening 44 of one second region 40, and another first trunk region 31 is located between two adjacent second regions 40. That is, each second opening 44 is provided therein with only one second trunk region 41.

Since D2<D5≤1.5D2 and D2<D6≤1.5D2, one second trunk region 41 can be arranged in the first opening 34, and one first trunk region 31 can be arranged in the second opening 44; in addition, it is conducive to providing a gap between the first trunk region 31 and the second trunk region 41, which is beneficial to separate the first region 30 from the second region 40 at the gap between the first trunk region 31 and the second trunk region 41 in the future.

For example, referring to FIG. 5, a plurality of through holes 61 are provided between adjacent first region 30 and second region 40, and a connection structure 62 is provided between two adjacent through holes 61. The connection structure 62 is used to connect and fix the adjacent first region 30 and second region 40. The connection structure 62 connects the first region 30 and the second region 40 into a one-piece structure, which facilitates the wiring on the first region 30 and the second region 40 of the substrate 2100 during the manufacturing of the wiring substrate. Connection structures 62 have therebetween a through hole 61 penetrating through the substrate 2100, which is conducive to reducing a contact area between the first region 30 and the second region 40, which is convenient for separating the first region 30 and the second region 40 in the subsequent manufacturing process to form independent structural components. A plurality of through holes 61 and a plurality of connection structures 62 together constitute a fourth region 60. A fourth region 60 separates two adjacent first regions 30, or separates two adjacent second regions 40, or separates adjacent first region 30 and second region 40. Therefore, any first region 30 and any second region 40 will be separated from the fourth region 60 to form structural components that are independent of each other.

For example, in an extending direction of an edge of the first region 30 or the second region 40, a length of the through hole 61 is greater than a length of the connection structure 62. In a direction perpendicular to an edge, connected to connection structure 62, of the first region 30 or the second region 40, a width of the connection structure 62 is M, and M may be in a range of 1 mm to 2 mm. For example, in a gap between the first trunk region 31 and the second trunk region 41 in the second direction Y, the width M of the connection structure 62 in the second direction Y is in a range of 1 mm to 2 mm; and in a gap between the first trunk region 31 and the second trunk region 41 in the first direction X, the width M of the connection structure 62 in the first direction X is in a range of 1 mm to 2 mm. For example, the width M of the connection structure 62 is 1 mm, 1.5 mm, or 2 mm.

In some other embodiments, as shown in FIGS. 3A and 4, the first interval D5 is greater than twice the dimension D2 of the second trunk region 41 in the second direction, and is less than or equal to 2.5 times the dimension D2 of the second trunk region 41 in the second direction Y. That is, 2D2<D5≤2.5D2. In this case, the two second trunk regions 41 of the second region 40 are respectively located in first intervals D5 of two adjacent first regions 30, and each first interval D5 is provided therein with only two second trunk regions 41.

The second interval D6 is greater than twice the dimension D2 of the first trunk region 31 in the second direction Y, and is less than or equal to 2.5 times the dimension D2 of the first trunk region 31 in the second direction. That is, 2D2<D6≤2.5D2. In this case, the two first trunk regions 31 of the first region 30 are respectively located in second openings 44 of two adjacent second regions 40, and one second opening 44 is provided therein with two first trunk regions 31 of two adjacent first regions 30. That is, each second opening 44 is provided therein with two first trunk regions 31.

Since 2D2<D5≤2.5D2 and 2D2<D6≤2.5D2, two second trunk regions 41, which are close to each other, of two adjacent second regions 40 may be arranged in the first opening 34, and two first trunk regions 31, which are close to each other, of two adjacent first regions 30 are arranged in the second opening 44; in addition, it is conducive to providing a gap between the first trunk region 31 and the second trunk region 41, which is beneficial to separate the first region 30 from the second region 40 at the gap between the first trunk region 31 and the second trunk region 41 in the future.

Referring to FIG. 3A, the substrate 2100 includes a plurality of first regions 30 sequentially arranged in the second direction Y, and a plurality of second regions 40 sequentially arranged in the second direction Y. Two first trunk regions 31, which respectively belong to two adjacent first regions 30 and have therebetween a smallest distance in the second direction Y, are located in the second opening 44 of the same second region 40. Two second trunk regions 41, which respectively belong to two adjacent second regions 40 and have therebetween a smallest distance in the second direction Y, are located in the first opening 34 of the same first region 30. Based on this, it is conducive to improving the space utilization of the wiring substrate 2000.

As shown in FIG. 3A, the substrate 2100 further includes two third regions 70. Each third region 70 extends in the first direction X. A third region 70 is located between a first trunk region 31 and a second trunk region 41 that are outermost in the second direction Y. The third region 70 is used to fill a gap between the first region 30 and the second region 40 that are outermost, so that the substrate 2100 is in a regular shape, which facilitates the stable connection between the first region 30 and the second region 40 that are outermost.

For example, any one of two outermost sides of the substrate 2100 in the second direction Y may be a first region 30 or a second region 40. For example, as shown in FIG. 3A, an upper side and a lower side of the substrate 2100 in the second direction Y are both first regions 30; or, as shown in FIG. 3B, the upper side of the substrate 2100 in the second direction Y is a first region 30, and the lower side is a second region 40. Of course, two sides of the substrate 2100 in the second direction Y may be second regions 40 (not shown in the figure); or, the upper side may be the second region 40 and the lower side may be the first region 30 (not shown in the figure).

With continued reference to FIG. 3A, a plurality of through holes 61 are provided between adjacent first region 30 and second region 40, a plurality of through holes 61 are provided between adjacent first region 30 and third region 70, a plurality of through holes 61 are provided between adjacent first regions 30, a plurality of through holes 61 are provided between adjacent second regions 40, and a plurality of through holes 61 are provided between adjacent second region 40 and third region 70. A connection structure 62 is provided between two adjacent through holes 61. The connection structure 62 is used to connect and fix the adjacent first region 30 and second region 40, the adjacent first region 30 and third region 70, the adjacent first regions 30, the adjacent second regions 40, or the adjacent second region 40 and third region 70. Connection structures 62 connect the first region 30, the second region 40 and the third region 70 to constitute a one-piece structure, which facilitates the wiring on the first region 30 and the second region 40 of the substrate 2100 during the manufacturing of the wiring substrate. Connection structures 62 have therebetween a through hole 61 penetrating through the substrate 2100, which is conducive to reducing a contact area between the first region 30, the second region 40 and the third region 70, which is convenient for separating the first region 30 and the second region 40 in the subsequent manufacturing process to form independent structural components.

In some embodiments, as shown in FIGS. 3A and 4, each first trunk region 31 of the first region 30 is provided with a plurality of electronic elements 50 that are arranged at intervals in the first direction X; and each second trunk region 41 of the second region 40 is provided with a plurality of electronic elements 50 that are arranged at intervals in the first direction X. For example, the electronic elements 50 are disposed in a middle of the first trunk region 31 in the second direction Y; and the electronic elements 50 are disposed in a middle of the second trunk region 41 in the second direction Y. A distance between two adjacent electronic elements 50 in the first direction X is D1. A width of a connection structure 62 in a direction perpendicular to a boundary, connected to the connection structure 62, of a first region 30 or a second region 40 is M.

A line connecting geometric centers of the plurality of electronic elements 50 in any first trunk region 31 (or any second trunk region 41) coincides with a center line of the first trunk region 31 (or the second trunk region 41) in the first direction X, and D1, D2 and M satisfy D2=(D1−3M)/3, that is D1=3D2+3M. As shown in FIG. 4, a distance between two adjacent electronic elements 50 in the second direction Y that are respectively on two first trunk regions 31 belonging to the same first region 30 is equal to a sum of the dimension (2*(1/2D2)) of one first trunk region 31 in the second direction Y, dimensions (2*D2) of two second trunk regions 41 in the second direction Y, and dimensions (3M) of three connection structures 62 in the second direction Y. Moreover, since the dimension of the first trunk region 31 in the second direction Y and the dimension of the second trunk region in the second direction Y are both D2, the distance between two adjacent electronic elements 50 in the second direction Y that are respectively on two first trunk regions 31 belonging to the same first region 30 is also D1, or a distance between two adjacent electronic elements 50 in the second direction Y that are respectively on two second trunk regions 41 belonging to the same second region 40 is also D1. As a result, the electronic elements 50 have the same distribution density in the first direction X and in the second direction Y.

In some embodiments, as shown in FIG. 3A, the first connection region 32 of the first region 30 is provided with a first connector 2200, and the second connection region 42 of the second region 40 is provided with a first connector 2200. An orthographic projection of a first connector 2200 on the substrate 2100 only partially overlaps with the first connection region 32 or the second connection region 42, which facilitates the electrical connection between the first connector 2200 and a second connector on the adapter circuit board. A structural component formed by cutting the wiring substrate is connected to the adapter circuit board through a first connector 2200, which is conducive to simplifying the assembly process between the structural component and the adapter circuit board and improving the assembly efficiency.

As shown in FIGS. 3A and 4, each first trunk region 31 of the first region 30 is provided with a plurality of driving elements 51, and each second trunk region 41 of the second region 40 is provided with a plurality of driving elements 51. The driving element 51 is configured to control at least one electronic element 50 in the same region (e.g., the same first trunk region 31 or the same second trunk region 41). For example, in the case where the electronic element 50 is a light-emitting element (e.g., a mini-LED chip), the driving element 51 may be a micro-integrated circuit chip. A single driving element 51 may control multiple light-emitting elements. The multiple light-emitting elements may be in a series connection, in a parallel connection, or in a combination of series connection and parallel connection; or, the multiple light-emitting elements may be independent of each other, which is not limited here.

In some embodiments, as shown in FIG. 3A, each first trunk region 31 of the first region 30 is provided with a plurality of fixing holes 52, and each second trunk region 41 of the second region 40 is provided with a plurality of fixing holes 52. The fixing holes 52 are used for fixing the structural component formed by the wiring substrate 2000 to other components, e.g., fixing the structural component to the backplane. The wiring substrate further includes an encapsulation adhesive (not shown in the figure), and each encapsulation adhesive covers a single electronic element 50 to protect the electronic element 50.

In some other embodiments, the embodiments of the present disclosure further provide a method for manufacturing a structural component. The method includes S100 to S700.

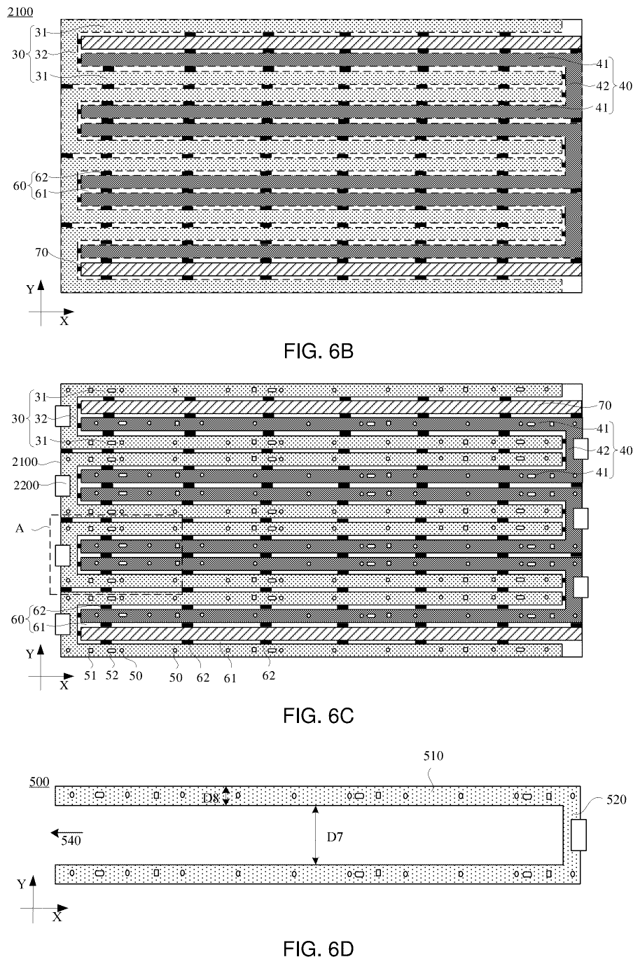

In S100, referring to FIG. 6A, a substrate 2100 is divided into first regions 30, second regions 40 and fourth regions 60.

The first region 30 includes two first trunk regions 31 and a first connection region 32. The two first trunk regions 31 extend in a first direction X and are spaced apart by a first interval D5 in a second direction Y. Ends of the first connection region 32 are respectively connected to ends of the two first trunk regions 31 located on the same side (e.g., left ends in FIG. 6A). The first region 30 has a first opening 34.

The second region 40 includes two second trunk regions 41 and a second connection region 42. The two second trunk regions 41 extend in the first direction X and are spaced apart by a second interval D6 in the second direction Y. Ends of the second connection region 42 are respectively connected to ends of the two second trunk regions 41 located on the same side (e.g., right ends in FIG. 6A). The second region 40 has a second opening 44. The first direction X and the second direction Y intersect.

An orientation of the second opening 44 is opposite to an orientation of the first opening 34. Therefore, the first trunk region 31 can extend into the second opening 44, and the second trunk region 41 can extend into the first opening 34. One first trunk region 31 of the first region 30 is located in the second opening 44, and one second trunk region 41 of the second region 40 is located in the first opening 34, which is conducive to increasing the space utilization of the substrate 2100.

A fourth region 60 is located between adjacent first region 30 and second region 40, a fourth region 60 is located between adjacent first regions 30, and a fourth region 60 is located between adjacent second regions 40. The fourth regions 60 are used to form cutting regions. In the subsequent process of manufacturing the structural component, the first regions 30 and the second regions 40 form independent structural components by cutting along the fourth regions 60.

It will be understood that the first region 30 and the second region 40 may be the first region 30 and the second region 40 described in any of the above embodiments, which will not be repeated here. Next, only the first region 30 and the second region 40 shown in FIG. 6A are taken as an example for exemplary description.

In S200, referring to FIG. 6B, portions of the fourth region 60 are removed. Therefore, a plurality of through holes 61 arranged at intervals are formed in the fourth region 60, and a connection structure 62 is formed between two adjacent through holes 61.

Through holes 61 penetrate through the substrate 2100, thereby reducing a connection region between first regions 30 and/or second regions 40, which is convenient for separating the first region 30 and the second region 40 in the future to form independent structural components. A connection structure 62 is used to connect and fix adjacent first regions 30 or second regions 40 or adjacent first region 30 and second region 40, which facilitates the wiring on the first region 30 and the second region 40 of the substrate 2100 during the manufacturing of the wiring substrate.

In S300, wiring is arranged on the first regions 30 and the second regions 40.

That is, circuit structures for transmitting electrical signals to electronic elements 50, driving elements and other electronic devices (such as first connectors) are formed on the first regions 30 and the second regions 40, including but not limited to forming at least one conductive layer and forming at least one insulating layer.

In S400, referring to FIG. 6C, electronic elements 50 are arranged on each first trunk region 31 of the first region 30 and each second trunk region 41 of the second region 40. That is, die bonding is performed on the first region 30 and the second region 40.

The electronic elements 50 may be, for example, light-emitting elements, sensors, or other components arranged in an array. In the case where the electronic elements 50 are light-emitting elements, the structural component is a light-emitting structural component, and the light-emitting structural component may be used to constitute a backlight source in a display apparatus. The light-emitting element is as described above and will not be repeated here.

In some embodiments, after S400 in which electronic elements 50 are arranged in each first trunk region 31 of the first region 30 and each second trunk region 41 of the second region 40, the method for manufacturing the structural component may further include encapsulating the electronic elements 50. For example, in the case where the electronic elements 50 are light-emitting elements, a protective adhesive (such as optical clear (OC) adhesive or ultraviolet (UV) adhesive) may be used to encapsulate the electronic elements 50.

In S500, as shown in FIG. 6C, first connectors 2200 are mounted on the first connection regions 32 and the second connection regions 42, which may also be referred to as performing mounted technology on the first connection regions 32 and the second connection regions 42, so that a first connector 2200 is bonded to the first connection region 32 of the first region 30 or the second connection region 42 of the second region 40.

In S600, the connection structures 62 are cut. As shown in FIG. 6D, the connection structures 62 are removed. Therefore, each of any first region 30 and any second region 40 that are independent of each other constitute a structural component 500.

As shown in FIG. 6D, the structural component 500 includes two first sub-portions 510 extending in the first direction X. The two first sub-portions 510 are arranged opposite to each other in the second direction Y. The two first sub-portions 510 have therebetween a third interval D7 in the second direction Y. The structural component 500 further includes a second sub-portion 520 located in the first interval D7, and two ends of the second sub-portion 520 in the second direction Y are respectively connected to two ends of the two first sub-portions 510 that are located on the same side. That is, the structural component 500 is of a U-shaped structure; and in the structural component 500, the third interval D7 is greater than a dimension D8 of the first sub-portion 510 in the second direction Y.

In some embodiments, after each of any first region 30 and any second region 40 that are independent constitute a structural component 500, the method for manufacturing the structural component 500 further includes S700.

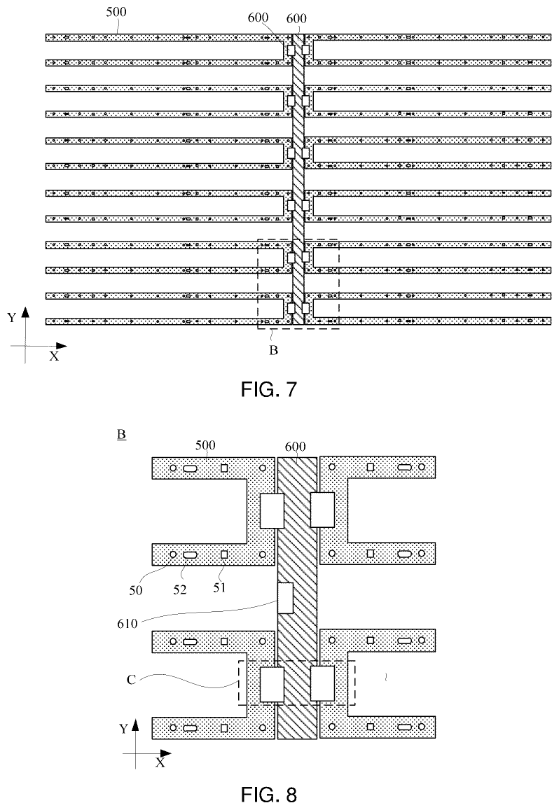

In S700, as shown in FIGS. 7 and 8, a adapter circuit board 600 is provided, and a plurality of structural components 500 are mounted on the adapter circuit board 600.

In the case where the structural components 500 are light-emitting structural components, the above S700 of mounting the plurality of structural components 500 on the adapter circuit board 600 may be used to form a light-emitting substrate. In the embodiments of the present disclosure, the structural component 500 is of a U-shaped structure. Compared with a linear structural component, the U-shaped structural component may reduce the usage amount of structural components and reduce the usage amount of first connectors 2200 and second connectors 2300 between the structural components 500 and the adapter circuit board 600, which is conducive to reducing the manufacturing cost of the light-emitting substrate composed of multiple structural components 500 and reducing the manufacturing cost of the display apparatus 1000.

Moreover, compared with setting the structural component 500 in a comb shape, setting the structural component 500 in a U shape has better universality and can be applied to backlight products of various sizes. When setting a light-emitting substrate, a quantity and arrangement density of the U-shaped light-emitting structural components are flexibly set according to the size of the light-emitting substrate.

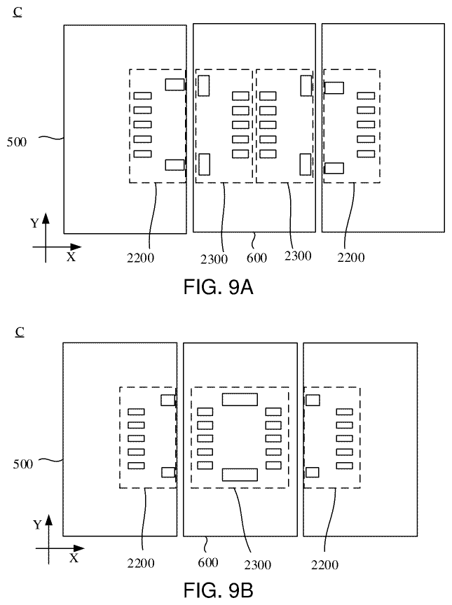

Referring to FIGS. 8, 9A and 9B, the adapter circuit board 600 extends in the second direction Y, and the adapter circuit board 600 is provided thereon with a plurality of second connectors 2300. A first connector 2200 of each structural component 500 is connected to a second connector 2300.

In some embodiments, two structural components 500 adjacent to each other in the first direction X are arranged on two sides of the adapter circuit board 600 in an axisymmetric manner. In this way, it is conducive to improving the distribution uniformity of the structural components 500, and in turn improves the distribution uniformity of electronic elements 50 on the structural components 500.

For example, as shown in FIG. 9A, the second connectors 2300 are arranged in two columns in the first direction X on the adapter circuit board 600, and the adapter circuit board 600 is located between two structural components 500 that are adjacent in the first direction X. Two first connectors 2200 of the two structural components 500 are respectively connected to two second connectors 2300 that are adjacent in the first direction X on the adapter circuit board 600.

Alternatively, as shown in FIG. 9B, the adapter circuit board 600 is provided with a plurality of second connectors 2300 in the second direction, and the adapter circuit board 600 is located between two structural components 500 that are adjacent in the first direction X. Two first connectors 2200 of the two structural components 500 may be connected to one second connector 2300.

In some embodiments, the first connector 2200 and the second connector 2300 may be Board-To-Board (BTB) connectors. The first connector 2200 and the second connector 2300 that are connected have the same quantity of connection terminals, and they are adapted to be connected and fixed by plugging.

For example, as shown in FIG. 8, the adapter circuit board 600 may further include a connection region 610, and the connection region 610 is configured to be electrically connected to an external control circuit board through an FPC.

The foregoing descriptions are merely specific implementations of the present disclosure, but the protection scope of the present disclosure is not limited thereto. Any changes or replacements that a person skilled in the art could conceive of within the technical scope of the present disclosure shall be included in the protection scope of the present disclosure. Therefore, the protection scope of the present disclosure should be determined by the protection scope of the claims.

1. A wiring substrate, comprising a substrate, the substrate including at least one first region and at least one second region, wherein
a first region of the at least one first region includes two first trunk regions and a first connection region; the two first trunk regions extend in a first direction and are spaced apart by a first interval in a second direction; ends of the first connection region are respectively connected to ends of the two first trunk regions located on a same side; the first region has a first opening; the first direction and the second direction intersect;
a second region of the at least one second region includes two second trunk regions and a second connection region; the two second trunk regions extend in the first direction and are spaced apart by a second interval in the second direction; ends of the second connection region are respectively connected to ends of the two second trunk regions located on a same side; the second region has a second opening; an orientation of the second opening is opposite to an orientation of the first opening; and
a first trunk region of the first region is located in the second opening, and a second trunk region of the second region is located in the first opening.

2. The wiring substrate according to claim 1, wherein a dimension of the first trunk region in the first direction is equal to a dimension of the second trunk region in the first direction; and/or a dimension of the first trunk region in the second direction is equal to a dimension of the second trunk region in the second direction.

3. The wiring substrate according to claim 1, wherein the first interval is equal to the second interval.

4. The wiring substrate according to claim 1, wherein
the first interval is greater than a dimension of the second trunk region in the second direction, and is less than or equal to 1.5 times the dimension of the second trunk region in the second direction;
the second interval is greater than a dimension of the first trunk region in the second direction, and is less than or equal to 1.5 times the dimension of the first trunk region in the second direction.

5. The wiring substrate according to claim 4, wherein a plurality of through holes are provided between a first region and a second region that are adjacent; a connection structure is provided between two adjacent through holes; and the connection structure is used to connect and fix the first region and the second region that are adjacent.

6. The wiring substrate according to claim 1, wherein
the first interval is greater than 2 times a dimension of the second trunk region in the second direction, and is less than or equal to 2.5 times the dimension of the second trunk region in the second direction;
the second interval is greater than 2 times a dimension of the first trunk region in the second direction, and is less than or equal to 2.5 times the dimension of the first trunk region in the second direction.

7. The wiring substrate according to claim 6, wherein the at least one first region includes a plurality of first regions sequentially arranged in the second direction, and the at least one second region includes a plurality of second regions sequentially arranged in the second direction;
two first trunk regions, which respectively belong to two adjacent first regions and have therebetween a smallest distance in the second direction, are located in a second opening of a same second region; and two second trunk regions, which respectively belong to two adjacent second regions and have therebetween a smallest distance in the second direction, are located in a first opening of a same first region.

8. The wiring substrate according to claim 7, wherein the substrate further includes a third region, and the third region extends in the first direction and is located between a first trunk region and a second trunk region that are outermost in the second direction.

9. The wiring substrate according to claim 7, wherein a plurality of through holes are provided between a first region and a second region that are adjacent, a plurality of through holes are provided between a first region and a third region that are adjacent, a plurality of through holes are provided between adjacent first regions, a plurality of through holes are provided between adjacent second regions, and a plurality of through holes are provided between a second region and a third region that are adjacent; a connection structure is provided between two adjacent through holes; the connection structure is used to connect and fix the first region and the second region that are adjacent, the first region and the third region that are adjacent, the adjacent first regions, the adjacent second regions, or the second region and the third region that are adjacent.

10. The wiring substrate according to claim 9, wherein each first trunk region of the first region is provided with a plurality of electronic elements arranged at intervals in the first direction, and each second trunk region of the second region is provided with a plurality of electronic elements arranged at intervals in the first direction; a distance between two adjacent electronic elements in the first direction is D1, a dimension of the first trunk region in the second direction and a dimension of the second trunk region in the second direction are both D2; a width of the connection structure in a direction perpendicular to a boundary, connected to the connection structure, of a first region or a second region is M; and D1, D2 and M satisfy D2=(D1−3M)/3.

11. The wiring substrate according to claim 10, wherein the width M of the connection structure in the direction perpendicular to the boundary, connected to the connection structure, of the first region or the second region is in a range of 1 mm to 2 mm.

12. The wiring substrate according to claim 1, wherein each of the first connection region of the first region and the second connection region of the second region is provided with a first connector; and an orthographic projection of a first connector corresponding to the first connection region on the substrate only partially overlaps with the first connection region, and an orthographic projection of a first connector corresponding to the second connection region on the substrate only partially overlaps with the second connection region.

13. The wiring substrate according to claim 1, wherein each of each first trunk region of the first region and each second trunk region of the second region is provided with a plurality of driving elements; and a driving element is configured to control at least one electronic element in a same region.

14. A method for manufacturing a structural component, comprising:
dividing a substrate into first regions, second regions and fourth regions, wherein a first region of the first regions includes two first trunk regions and a first connection region; the two first trunk regions extend in a first direction and are spaced apart by a first interval in a second direction; ends of the first connection region are respectively connected to ends of the two first trunk regions located on a same side; a second region of the second regions includes two second trunk regions and a second connection region; the two second trunk regions extend in the first direction and are spaced apart by a second interval in the second direction; ends of the second connection region are respectively connected to ends of the two second trunk regions located on a same side; the second region has a second opening; an orientation of the second opening is opposite to an orientation of the first opening; a fourth region of the fourth regions is located between a first region and a second region that are adjacent, a fourth region is located between adjacent first regions, and a fourth region is located between adjacent second regions; and the first direction and the second direction intersect;
removing portions of the fourth region, so that a plurality of through holes are formed in the fourth region and arranged at intervals, and a connection structure is formed between two adjacent through holes;
arranging wiring on the first regions and the second regions;
arranging electronic elements on each first trunk region of the first region and each second trunk region of the second region;
mounting first connectors on the first connection regions and the second connection regions; and
cutting connection structures, so that each of any first region and any second region that are independent of each other constitute a structural component.

15. The method according to claim 14, after each of any first region and any second region that are independent of each other constitute a structural component, the method further comprises:
providing a adapter circuit board, wherein the adapter circuit board extends in the second direction, and a plurality of second connectors are provided on the adapter circuit board; and
mounting a plurality of structural components on the adapter circuit board, wherein a first connector of each structural component is connected to a second connector.

16. The method according to claim 15, wherein
two structural components adjacent to each other in the first direction are arranged on two sides of the adapter circuit board in an axisymmetric manner.

17. A display apparatus, comprising:
a plurality of structural components formed by the method according to claim 14, wherein the electronic elements include light-emitting elements; and
a display panel, wherein the plurality of structural components are disposed on a non-display side of the display panel.

18. The display apparatus according to claim 17, wherein in the structural component, a dimension of the first trunk region in the first direction is equal to a dimension of the second trunk region in the first direction; and/or a dimension of the first trunk region in the second direction is equal to a dimension of the second trunk region in the second direction.

19. The wiring substrate according to claim 2, wherein
the first interval is greater than a dimension of the second trunk region in the second direction, and is less than or equal to 1.5 times the dimension of the second trunk region in the second direction;
the second interval is greater than a dimension of the first trunk region in the second direction, and is less than or equal to 1.5 times the dimension of the first trunk region in the second direction.

20. The The wiring substrate according to claim 2, wherein
the first interval is greater than 2 times a dimension of the second trunk region in the second direction, and is less than or equal to 2.5 times the dimension of the second trunk region in the second direction;
the second interval is greater than 2 times a dimension of the first trunk region in the second direction, and is less than or equal to 2.5 times the dimension of the first trunk region in the second direction.
